(19) United States
(12) Patent Application Publication
(10) Pub. No.: US 2010/0200040 A1
(43) Pub. Date: Aug. 12, 2010

(54) DEVICE AND METHOD FOR REPAIRING SOLAR CELL MODULE

(75) Inventors: Chun Heng Chen, Taipei City (TW); Yi Chan Chen, Yunlin County (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: Industrial Technology Research Institute, Hsin-Chu (TW)

(21) Appl. No.: 12/464,513

(22) Filed: May 12, 2009

(30) Foreign Application Priority Data
Feb. 6, 2009 (TW) 098103937

(51) Int. Cl. H01L 31/042

(52) U.S. Cl. 136/244

(57) ABSTRACT

A device for repairing a solar cell module is described. The solar cell module includes a first solar cell and a second solar cell serially connected to each other. The device for repairing the solar cell module includes a first terminal, a second terminal, and a power supply device. The power supply device applies a biased voltage signal to the solar cells via the first terminal and the second terminal. The biased voltage signal includes a forward biased voltage part and a reversed biased voltage part. The reversed biased voltage part has multiple voltage bands arranged by time, and a voltage value of each voltage band is a fixed value. The voltage value of the earlier-generated voltage band is greater than the voltage value of the later-generated voltage band, and a duration of the reversed biased voltage part is longer than a duration of the forward biased voltage part.

### CROSS-REFERENCE TO RELATED APPLICATIONS

This non-provisional application claims priority under 35 U.S.C. § 119(a) on Patent Application No(s). 098103937 filed in Taiwan, R.O.C. on Feb. 6, 2009 the entire contents of which are hereby incorporated by reference.

### BACKGROUND OF THE INVENTION

1. Field of Invention

The present invention relates to a device and a method for manufacturing a solar cell module, in particular, to a device and a method for repairing a solar cell module.

2. Related Art

As countries all over the world attach great importance to green energy sources, the thin film solar cell market quickly grows. FIGS. 1A to 1F are schematic views of a process for manufacturing a thin film solar cell module in the conventional art. Referring to FIG. 1A, firstly, a glass substrate 110 is provided, and a surface of the glass substrate 110 has a transparent conductive oxide (TCO) layer thin film 120. Referring to FIG. 1B, a plurality of openings P1 is then formed on the TCO layer thin film 120 by means of laser ablation, and the TCO layer thin film 120 is divided into a plurality of TCO layers 120a separated from each other by the openings P1.

Referring to FIG. 1C, a photovoltaic layer 130 is formed on the TCO layers 120a and the glass substrate 110. Referring to FIG. 1D, a plurality of openings P2 is formed on the photovoltaic layer 130 by means of laser ablation. The openings P2 are located on the TCO layers 120a, and expose a part of the TCO layers 120a. Referring to FIG. 1E, a back electrode thin film 140 is formed on the photovoltaic layer 130 and the TCO layers 120a. A part of a material of forming the back electrode thin film 140 is filled in the openings P2, and electrically contacts the TCO layers 120a. Referring to FIG. 1F, a plurality of openings P3 is formed on the back electrode thin film 140 by means of laser ablation. The openings P3 are located above the TCO layers 120a, penetrate the back electrode thin film 140 and the photovoltaic layer 130, and expose a part of the TCO layers 120a. In addition, the back electrode thin film 140 is divided into a plurality of back electrode layers 140a separated from each other by the openings P3, so as to form a thin film solar cell module 100. The thin film solar cell module 100 has a plurality of solar cells 100′ serially connected to each other.

Based on the above manufacturing process, the conventional art has the following problems. FIG. 2 is a schematic enlarged view of a region Q in FIG. 1F. Generally, the photovoltaic layer 130 is formed by stacking a P-type semiconductor layer 132, an intrinsic semiconductor layer 134 (also referred to as I-type semiconductor layer), and an N-type semiconductor layer 136. The P-type semiconductor layer 132 contacts the TCO layer 120a, and the intrinsic semiconductor layer 134 is sandwiched between the P-type semiconductor layer 132 and the N-type semiconductor layer 136. During the process of forming the openings P3, as the laser power is insufficient or the laser head is aged, a plurality of semiconductor crystals 150 or residual thin films that are not removed are formed on walls of the photovoltaic layer 130 where the openings P3 are made, thereby lowering the capability of the photovoltaic layer 130 in converting lights into an electric energy.

For example, when the semiconductor crystal 150 or the residual thin film is located on a boundary position of the P-type semiconductor layer 132 and the intrinsic semiconductor layer 134, and the P-type semiconductor layer 132 and the intrinsic semiconductor layer 134 form an electrical short circuit, the semiconductor crystal 150 or the residual thin film may lower the power generation capacity of the thin film solar cell module 100. Similarly, when the semiconductor crystal 150 or the residual thin film is located on a boundary position of N-type semiconductor layer 136 and the intrinsic semiconductor layer 134, and the N-type semiconductor layer 136 and the intrinsic semiconductor layer 134 form an electrical short circuit, the semiconductor crystal 150 or the residual thin film also lowers the power generation capacity of the thin film solar cell module 100.

In view of the above problems, in U.S. Pat. No. 6,228,662 B1 and U.S. Pat. No. 6,365,825 B1 of the conventional art, a technique of oxidizing the semiconductor crystals 150 or the residual thin films by using the Joule heating effect is described, so as to repair the thin film solar cell module 100 and resume the power generation capacity of the thin film solar cell module 100. However, in U.S. Pat. No. 6,228,662 B1 and U.S. Pat. No. 6,365,825 B1, the repairing time course is too long.

### SUMMARY OF THE INVENTION

In order to solve the above problems, the present invention is a device and a method for repairing a solar cell module, so as to shorten a time course of repairing defects of the solar cell module.

A device for repairing a solar cell module is adapted to repair a solar cell module comprising a first solar cell and a second solar cell serially connected to each other. The repairing device comprises a first terminal, a second terminal, and a power supply device. The first terminal is electrically connected to a first electrode layer of the first solar cell, the second terminal is electrically connected to a second electrode layer of the second solar cell, and a polarity of the first electrode layer is the same as that of the second electrode layer. The power supply device is electrically connected to the first terminal and the second terminal. The power supply device generates a biased voltage signal. The biased voltage signal is transmitted to the first solar cell and the second solar cell through the first terminal and the second terminal. The biased voltage signal comprises a forward biased voltage part and a reversed biased voltage part. A voltage value of the forward biased voltage part is greater than zero, and a voltage value of the reversed biased voltage part is smaller than zero. The reversed biased voltage part has a plurality of voltage bands arranged by time. A voltage value of each voltage band is a fixed value. The voltage value of the earlier-generated voltage band is greater than the voltage value of the later-generated voltage band. A duration of the reversed biased voltage part is longer than that of the forward biased voltage part.

According to a preferred embodiment of the present invention, the forward biased voltage part is generated after the reversed biased voltage part. Preferably, the biased voltage signal comprises a plurality of continuous reversed biased voltage parts, and the forward biased voltage part is generated after the reversed biased voltage parts.

According to the preferred embodiment of the present invention, the voltage value of the forward biased voltage part is a fixed value.

According to the preferred embodiment of the present invention, the power supply device is a direct current (DC) power generator.

According to the preferred embodiment of the present invention, the power supply device is a pulse generator.

According to the preferred embodiment of the present invention, an absolute value of the voltage value of any voltage band in the reversed biased voltage part does not exceed a breakdown voltage of the first solar cell and the second solar cell.

According to the preferred embodiment of the present invention, the voltage value of the forward biased voltage part does not exceed an open circuit voltage value of the first solar cell and the second solar cell.

According to the preferred embodiment of the present invention, the device for repairing a solar cell module comprises a plurality of first terminals and a plurality of second terminals.

A method for repairing a solar cell module comprises the following steps. A solar cell module comprising a first solar cell and a second solar cell serially connected to each other is provided. A first terminal is electrically connected to a first electrode layer of the first solar cell, a second terminal is electrically connected to a second electrode layer of the second solar cell, and a polarity of the first electrode layer is the same as that of the second electrode layer. A biased voltage signal is generated, and transmitted to the first solar cell and the second solar cell through the first terminal and the second terminal. The biased voltage signal comprises a forward biased voltage part and a reversed biased voltage part. A voltage value of the forward biased voltage part is greater than zero, and a voltage value of the reversed biased voltage part is smaller than zero. The reversed biased voltage part has a plurality of voltage bands arranged by time. A voltage value of each voltage band is a fixed value. The voltage value of the earlier-generated voltage band is greater than the voltage value of the later-generated voltage band. A duration of the reversed biased voltage part is longer than that of the forward biased voltage part.

According to a preferred embodiment of the present invention, the forward biased voltage part is generated after the reversed biased voltage part. Preferably, the biased voltage signal comprises a plurality of continuous reversed biased voltage parts, and the forward biased voltage part is generated after the reversed biased voltage parts.

According to the preferred embodiment of the present invention, the voltage value of the forward biased voltage part is a fixed value.

According to the preferred embodiment of the present invention, an absolute value of the voltage value of any voltage band in the reversed biased voltage part does not exceed a breakdown voltage of the first solar cell and the second solar cell.

According to the preferred embodiment of the present invention, the voltage value of the forward biased voltage part does not exceed an open circuit voltage value of the first solar cell and the second solar cell.

According to the preferred embodiment of the present invention, the solar cell module further comprises at least one third solar cell, and the first solar cell is serially connected to the second solar cell through the third solar cells. Preferably, the third solar cells are serially connected between the first solar cell and the second solar cell.

A device for repairing a solar cell module is adapted to repair a solar cell module comprising a first solar cell and a second solar cell serially connected to each other. The repairing device comprises a first terminal, a second terminal, and a power supply device. The first terminal is electrically connected to a first electrode layer of the first solar cell, the second terminal is electrically connected to a second electrode layer of the second solar cell, and a polarity of the first electrode layer is the same as that of the second electrode layer. The power supply device is electrically connected to the first terminal and the second terminal. The power supply device generates a biased voltage signal. The biased voltage signal is transmitted to the first solar cell and the second solar cell through the first terminal and the second terminal. The biased voltage signal comprises a forward biased voltage part and a reversed biased voltage part. A voltage value of the forward biased voltage part is greater than zero, and a voltage value of the reversed biased voltage part is smaller than zero. The voltage value of the reversed biased voltage part is a fixed value, and a duration of the reversed biased voltage part is longer than that of the forward biased voltage part.

Based on the above, a waveform of the reversed biased voltage part in the biased voltage signal of the present invention is in a step-like shape, such that as compared with the waveform of the biased voltage signal in U.S. Pat. No. 6,228,662 B1 and U.S. Pat. No. 6,365,825 B1 in the conventional art, the waveform of the biased voltage signal of the present invention may effectively shorten a repairing time course. In addition, in the present invention, the thin film solar cell module is repaired by a plurality of continuous reversed biased voltage parts, and a forward biased voltage part is applied after the continuous reversed biased voltage parts to eliminate charges accumulated in the thin film solar cell module, such that through the continuous reversed biased voltage parts, the present invention may further reduce the time course of repairing the thin film solar cell module.

### BRIEF DESCRIPTION OF THE DRAWINGS

The present invention will become more fully understood from the detailed description given herein below for illustration only, and thus are not limitative of the present invention, and wherein:

FIGS. 1A to 1F are schematic views of a process for manufacturing a thin film solar cell module in the conventional art;

FIG. 2 is a schematic enlarged view of a region Q in FIG. 1F;

FIG. 3 is a schematic view of a device for repairing a solar cell module according to an embodiment of the present invention;

FIG. 4 is a schematic view of a biased voltage signal output from a power supply device in FIG. 3;

FIG. 5 is a schematic view of a biased voltage signal according to another embodiment of the present invention; and

FIG. 6 is a schematic view of a biased voltage signal S according to still another embodiment of the present invention.

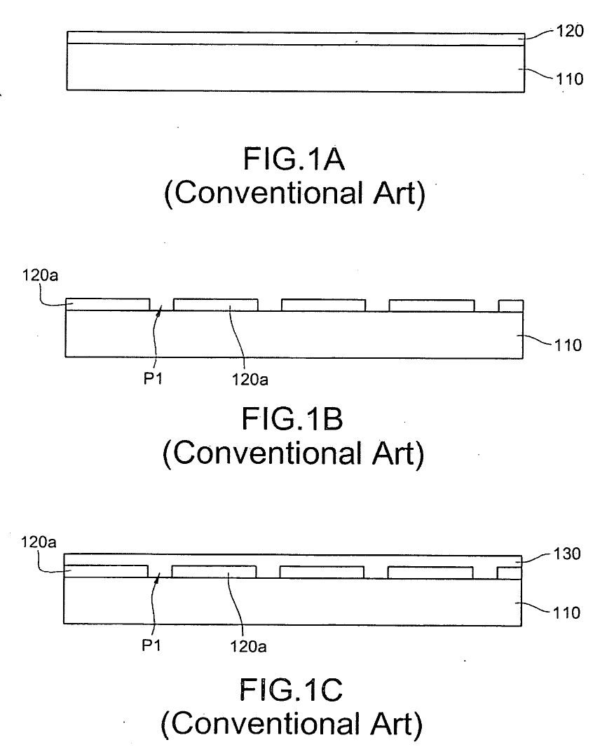

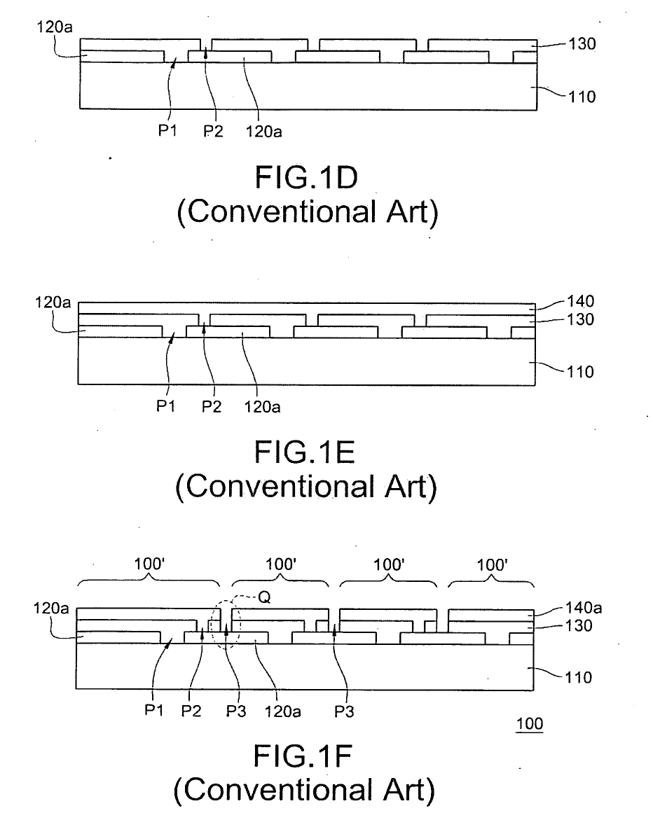

### DETAILED DESCRIPTION OF THE INVENTION

The detailed features and advantages of the present invention will be described in detail in the following embodiments. Those skilled in the arts can easily understand and implement the content of the present invention. Furthermore, the relative objectives and advantages of the present invention are apparent to those skilled in the arts with reference to the content disclosed in the specification, claims, and drawings. The embodiments below are intended to further describe the views of the present invention instead of limiting the scope of the same.

FIG. 3 is a schematic view of a device for repairing a solar cell module according to an embodiment of the present invention. The device 200 is adapted to repair a solar cell module. For ease of description, in this embodiment, a solar cell module 300 of FIG. 3 serves as a repaired object, so as to give a detailed description of the device 200 for repairing the solar cell module.

The solar cell module 300 has a plurality of solar cells 300′. The solar cell 300′ comprises a substrate 310, a TCO layer 320, a photovoltaic conversion layer 330, and a back electrode layer 340. The TCO layer 320, the photovoltaic layer 330, and the back electrode layer 340 are stacked on the substrate 310 in sequence. A material of the substrate 310 is, for example, glass or resin, so that the substrate 310 has excellent insulativity. A material of the transparent electrode layer 320 is, for example, indium tin oxide (ITO), ZnO, SnO₂, or other transparent conductive materials. A material of the photovoltaic layer 330 is, for example, an amorphous silicon-based semiconductor or a GaAs-based material. A material of the back electrode layer 340 may be silver, ZnO, or other conductive materials. It should be noted that, positions of the TCO layer 320 and the back electrode layer 340 are not used to limit the types of the cells applicable to the device 200 for repairing the solar cell module of the present invention. In other embodiments of the present invention, the back electrode layer 340 of the repaired solar cell 300′ may contact the substrate 310, and the photovoltaic layer 330 is located between the transparent electrode layer 320 and the back electrode layer 340.

In the solar cell module 300 of this embodiment, one solar cell 300′ is serially connected to another adjacent solar cell 300′ through a conductive post 342. More particularly, the back electrode layer 340 of one solar cell 300′ is electrically connected to the back electrode layer of another adjacent solar cell 300′ through the conductive post 342.

The device 200 for repairing the solar cell module comprises a first terminal 210, a second terminal 220, and a power supply device 230. The first terminal 210 is electrically connected to the back electrode layer 340 of one solar cell 300′. The second terminal 220 is electrically connected to the back electrode layer 340 of another solar cell 300′. In this embodiment, multiple other solar cells 300′ are serially connected between the two solar cells 300′ electrically connected to the first terminal 210 and the second terminal 220. However, in other embodiments of the present invention, the two solar cells 300′ respectively electrically connected to the first terminal 210 and the second terminal 220 may be directly serially connected to each other, that is, no additional solar cells 300′ are not serially connected between the two solar cells 300′.

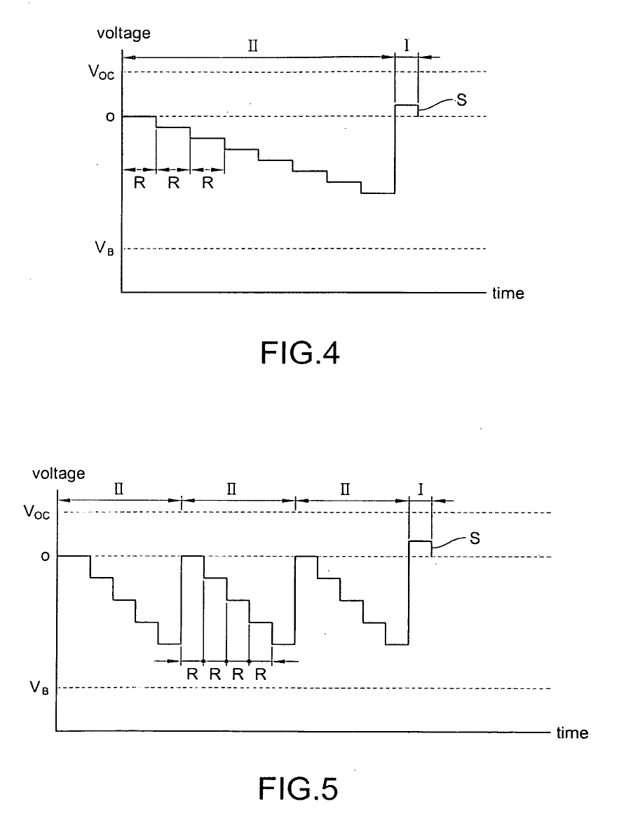

The power supply device 230 is electrically connected between the first terminal 210 and the second terminal 220. The power supply device 230 is, for example, a pulse generator or a DC power generator, and is used to generate a biased voltage signal. FIG. 4 is a schematic view of a biased voltage signal S output from the power supply device 230 in FIG. 3. After the first terminal 210 and the second terminal 220 are electrically connected to the two corresponding back electrode layers 340, and after the power supply device 230 generates the biased voltage signal S, the biased voltage signal S is transmitted to the solar cells 300′ electrically connected to the first terminal 210 and the second terminal 220 through the first terminal 210 and the second terminal 220.

The biased voltage signal S has a forward biased voltage part I and a reversed biased voltage part II. In this embodiment, the photovoltaic layer 330 is formed by stacking a P-type semiconductor layer, an intrinsic semiconductor layer, and an N-type semiconductor layer. For a definition of the forward biased voltage part I, in an external voltage applied to the solar cell 300′, the voltage flowing from the P-type semiconductor layer to the N-type semiconductor layer internally forms the forward biased voltage, and for a definition of the reversed biased voltage part II, in the external voltage applied to the solar cell 300′, the voltage flowing from the N-type semiconductor layer to the P-type semiconductor layer internally forms the reversed biased voltage.

The reversed biased voltage part II has multiple voltage bands R arranged by time. A voltage value of each voltage band R is a fixed value, and the voltage value (being a negative number) of any voltage band in the reversed biased voltage part II is greater than a breakdown voltage value VB (being a negative number) of the solar cells 300′. The voltage value of the earlier-generated voltage band R is greater than the voltage value of the later-generated voltage band R. In other words, a waveform of the reversed biased voltage part II of this embodiment is in a step-like shape, and the voltage value of the step-like reversed biased voltage part II is increasingly decreased as time goes by. In addition, a duration of the reversed biased voltage part II is longer than that of the forward biased voltage part I. In this embodiment, the forward biased voltage part I is a fixed value, and the voltage value of the forward biased voltage part I is smaller than an open circuit voltage value V_{OC} of the solar cells 300′.

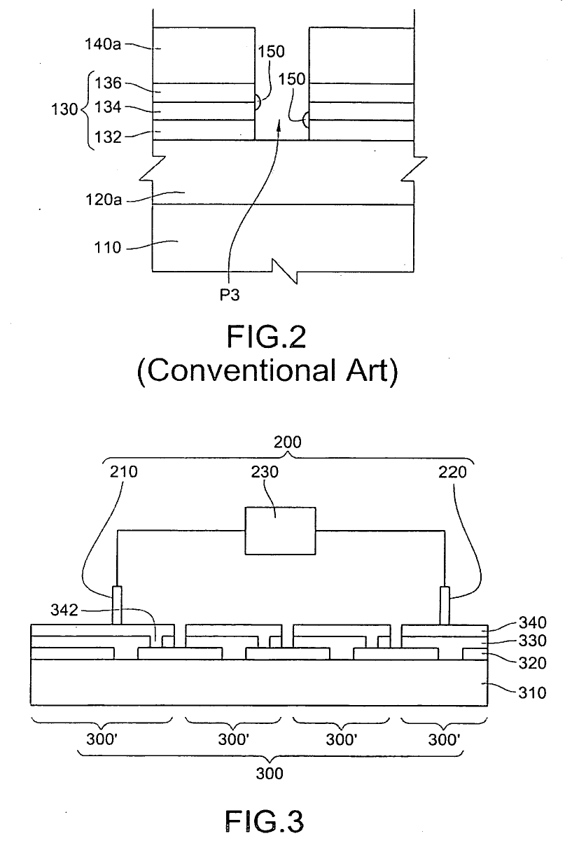

Based on the above structure, the waveform of the reversed biased voltage part II in this embodiment is in a step-like shape, such that under a unit time and a fixed voltage drop, the step-like waveform of the reversed biased voltage of this embodiment may provide relatively more energy to the semiconductor crystals or residual thin films 150 that are not completely removed (referring to FIG. 2), so as to oxidize the semiconductor crystals or the residual thin films 150. After the semiconductor crystals 150 or the residual thin films are oxidized, the forward biased voltage part I after the reversed biased voltage part II may be further applied to eliminate electrons and holes accumulated in the solar cells 300′, which are generated during the process of removing (oxidizing) the semiconductor crystals 150 or the residual thin films.

It should be noted that, in the above embodiment, although a pair of the first terminal 210 and the second terminal 220 are used to respectively electrically contact the back electrode layers 340 of a pair of solar cells 300′, this embodiment is not intended to limit the number of the first terminal 210 and the second terminal 220 in the present invention. In still another embodiment of the present invention, the device 200 for repairing the solar cell module further has multiple pairs of the first terminals 210 and the second terminals 220, and the first terminals 210 and the second terminals 220 are electrically connected to the power supply device 230. Thereby, in this embodiment, each pair of the first terminal 210 and the second terminal 220 electrically contact the two corresponding back electrode layers 340, such that the biased voltage signal S is output to the solar cells 300′ at the same time through equipotential, so as to repair a part of the solar cells 300′. Afterward, in this embodiment, polarities of the first terminal 210 and the second terminal 220 are exchanged by a switching device of the power supply device 230, and the biased voltage signal S is output to repair the remaining solar cells 300′, wherein the switching device is electrically connected to the first terminal 210 and the second terminal 220. Therefore, in this embodiment, the semiconductor crystals 150 or the residual thin films in the solar cells 300′ are removed (oxidized) at the same time through the plurality of pairs of the first terminals 210 and the second terminals 220.

FIG. 5 is a schematic view of a biased voltage signal S according to another embodiment of the present invention. The biased voltage signal S further has a forward biased voltage part I and multiple continuous reversed biased voltage parts II. That is, a reversed biased voltage part II is directly connected to an end of another reversed biased voltage part II, and then the forward biased voltage part I is directly connected to an end of the last reversed biased voltage part II. In this manner, after accepting the energy from the continuous reversed biased voltage parts II and being oxidized, the semiconductor crystals 150 or the residual thin films in the solar cells 300′ accept the energy from the forward biased voltage part I. Therefore, under the same time, as compared with the conventional art, the present invention may achieve the same repairing effect through a shorter repairing time course.

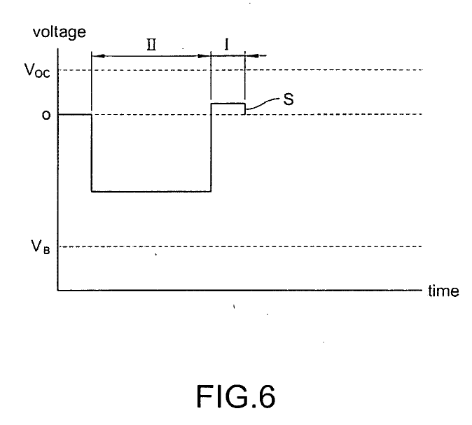

FIG. 6 is a schematic view of a biased voltage signal S according to still another embodiment of the present invention. In addition to the step-like waveform of the reversed biased voltage part II, in still another embodiment of the present invention, the voltage value of the reversed biased voltage part II is a fixed value. Therefore, by using the reversed biased voltage part II as shown in FIG. 6, in this embodiment, the time of repairing the solar cells 300′ of the present invention is further reduced.

To sum up, the waveform of the reversed biased voltage part of the present invention is in a step-like shape, such that under a unit time and a fixed voltage drop, the step-like waveform of the reversed biased voltage of the present invention may provide relatively more energy to the semiconductor crystals or residual thin films that are not completely removed, so as to oxidize the semiconductor crystals or the residual thin films. In addition, the biased voltage signal of the present invention may further have a plurality of continuous reversed biased voltage parts, so that under the same time, as compared with the conventional art, the present invention may achieve the same repairing effect through a shorter repairing time course.

What is claimed is:

1. A device for repairing a solar cell module, adapted to repair a solar cell module comprising a first solar cell and a second solar cell serially connected to each other, the device comprising:
a first terminal, electrically connected to a first electrode layer of the first solar cell;
a second terminal, electrically connected to a second electrode layer of the second solar cell, wherein a polarity of the first electrode layer is the same as a polarity of the second electrode layer; and
a power supply device, electrically connected to the first terminal and the second terminal, for generating a biased voltage signal, wherein the biased voltage signal is transmitted to the first solar cell and the second solar cell through the first terminal and the second terminal, the biased voltage signal comprises a forward biased voltage part and a reversed biased voltage part, the reversed biased voltage part has a plurality of voltage bands arranged by time, a voltage value of each voltage band is a fixed value, the voltage value of the earlier-generated voltage band is greater than the voltage value of the later-generated voltage band, and a duration of the reversed biased voltage part is longer than a duration of the forward biased voltage part.

2. The device for repairing a solar cell module according to claim 1, wherein the forward biased voltage part is generated after the reversed biased voltage part.

3. The device for repairing a solar cell module according to claim 1, wherein the biased voltage signal comprises a plurality of continuous reversed biased voltage parts, and the forward biased voltage part is generated after the reversed biased voltage parts.

4. The device for repairing a solar cell module according to claim 1, wherein a voltage value of the forward biased voltage part is a fixed value.

5. The device for repairing a solar cell module according to claim 1, wherein the power supply device is a direct current (DC) power generator.

6. The device for repairing a solar cell module according to claim 1, wherein the power supply device is a pulse generator.

7. The device for repairing a solar cell module according to claim 1, wherein an absolute value of the voltage value of any voltage band in the reversed biased voltage part does not exceed a breakdown voltage of the first solar cell and the second solar cell.

8. The device for repairing a solar cell module according to claim 1, wherein a voltage value of the forward biased voltage part does not exceed an open circuit voltage value (V_{OC}) of the first solar cell and the second solar cell.

9. The device for repairing a solar cell module according to claim 1, wherein the power supply device has a switching device, and the switching device is connected to the first terminal and the second terminal, so as to exchange polarities of the first terminal and the second terminal.

10. The device for repairing a solar cell module according to claim 1, further comprising a plurality of first terminals and a plurality of second terminals.

11. A method for repairing a solar cell module, comprising:
providing a solar cell module, comprising a first solar cell and a second solar cell serially connected to each other;
electrically connecting a first terminal to a first electrode layer of the first solar cell, and electrically connecting a second terminal to a second electrode layer of the second solar cell, wherein a polarity of the first electrode layer is the same as a polarity of the second electrode layer; and
generating a biased voltage signal, and transmitting the biased voltage signal to the first solar cell and the second solar cell through the first terminal and the second terminal, wherein the biased voltage signal comprises a forward biased voltage part and a reversed biased voltage part, a voltage value of the forward biased voltage part is greater than zero, a voltage value of the reversed biased voltage part is smaller than zero, and the voltage value of the reversed biased voltage part is increasingly decreased in a step-like manner as time goes by.

12. The method for repairing a solar cell module according to claim 11, wherein the forward biased voltage part is generated after the reversed biased voltage part.

13. The method for repairing a solar cell module according to claim 12, wherein the biased voltage signal comprises a plurality of continuous reversed biased voltage parts, and the forward biased voltage part is generated after the reversed biased voltage parts.

14. The method for repairing a solar cell module according to claim 11, wherein the voltage value of the forward biased voltage part is a fixed value.

15. The method for repairing a solar cell module according to claim 11, wherein an absolute value of the voltage value of any voltage band in the reversed biased voltage part does not exceed a breakdown voltage of the first solar cell and the second solar cell.

16. The method for repairing a solar cell module according to claim 11, wherein the voltage value of the forward biased voltage part does not exceed an open circuit voltage value (V_{OC}) of the first solar cell and the second solar cell.

17. The method for repairing a solar cell module according to claim 11, wherein the solar cell module further comprises at least one third solar cell, and the first solar cell is serially connected to the second solar cell through the third solar cells.

18. The method for repairing a solar cell module according to claim 17, wherein the third solar cells are serially connected between the first solar cell and the second solar cell.

19. A device for repairing a solar cell module, adapted to repair a solar cell module comprising a first solar cell and a second solar cell serially connected to each other, the device comprising:
a first terminal, electrically connected to a first electrode layer of the first solar cell;
a second terminal, electrically connected to a second electrode layer of the second solar cell, wherein a polarity of the first electrode layer is the same as a polarity of the second electrode layer; and
a power supply device, electrically connected to the first terminal and the second terminal, for generating a biased voltage signal, wherein the biased voltage signal is transmitted to the first solar cell and the second solar cell through the first terminal and the second terminal, the biased voltage signal comprises a forward biased voltage part and a reversed biased voltage part, a voltage value of the reversed biased voltage part is a fixed value, and a duration of the reversed biased voltage part is longer than a duration of the forward biased voltage part.
